(19) United States
(12) Patent Application Publication
(10) Pub. No.: US 2012/0247535 A1
(43) Pub. Date: Oct. 4, 2012

(54) SYSTEM AND METHOD FOR THE GENERATION OF ELECTRICAL POWER FROM SUNLIGHT

(75) Inventors: Daniel McGlynn, Albuquerque, NM (US); Mark A. Stan, Albuquerque, NM (US)

(73) Assignee: Emcore Solar Power, Inc., Albuquerque, NM (US)

(21) Appl. No.: 13/524,523

(22) Filed: Jun. 15, 2012

Related U.S. Application Data
(63) Continuation-in-part of application No. 12/349,244, filed on Jan. 6, 2009.

(51) Int. Cl. H01L 31/052; H01L 31/042

(52) U.S. Cl. 136/246; 136/244

(57) ABSTRACT

A system for the generation of electrical power from sunlight includes a solar cell assembly with at least two sets of solar cells, each of these sets being adapted to a set-specific light frequency spectrum so as to convert light having said set-specific frequency spectrum into electrical energy with an optimized energy conversion efficiency. The system is arranged to respond to changes in the frequency spectrum of the sunlight, for example, in accordance with the time of the day, by causing the sunlight to selectively impinge on one or another of the different sets of solar cells. Thus, an enhanced energy conversion efficiency of the system is obtained.

This application is a continuation-in-part of U.S. application Ser. No. 12/349,244, filed Jan. 6, 2009, which is incorporated herein by reference in its entirety.

### FIELD OF THE INVENTION

The invention relates to a system and method for the generation of electrical power from sunlight utilizing sets of solar cells with different spectral response.

### STATE OF THE ART

Systems for the conversion of solar power into electrical power are well known in the art. Many of these systems are based on the photovoltaic effect and include solar cells. A solar cell is a device that converts solar energy into electricity by said photovoltaic effect. Assemblies of such cells are used to make so-called solar modules, and these modules can be linked to fowi what is often referred to as photovoltaic arrays.

Basically, it can be said that electricity is produced in a solar cell when photons hit the solar cell and are absorbed by a material of the solar cell, such as a semi-conducting material. Electrons can then be knocked off from their atoms by photons, whereby free electron and hole carriers are produced. In order to generate useful electrical energy, an electric field or a gradient of chemical potential can be applied to the so-called photoactive region in order to drive the carriers towards negative and positive electrodes.

When a photon hits a solar cell its energy is not always completely converted into electrical energy. Basically, there are several possibilities: the photon can pass through the photoactive region of the solar cell; the photon can be reflected off the solar cell; or if the photon energy is at least as high as the band gap value of the material of the photoactive region, the photon can be absorbed by the solar cell, generating an electron-hole pair and, if the photon energy is higher than the band gap value, also excess energy, basically in the faun of heat. This excess energy can be considered as a loss, reducing the efficiency of the solar cell.

Photons with energy below the band gap of the absorbing material will not be able to generate an electron-hole pair and thus represent a loss. On the other hand, photons with an energy above the band gap of the material can be absorbed and create an electron-hole pair, but the corresponding “electrical energy” created corresponds, at the most, to the band gap value; the rest of the photon energy is thus lost.

Thus, the efficiency of the solar cell will depend, inter alia, on the relation between the band gap value of the solar cell and the photon energy of the incoming photons (that is, on the wavelength of the light that impinges on the solar cell). A high band gap value material can be useful for converting high energy photons into electrical energy with a minimum loss of energy in the form of heat, but lower energy photons will not be absorbed and the corresponding energy is thus lost. A low band gap value material can sometimes be preferred as it can absorb also photons having a lower energy, but the higher energy photons will be absorbed “inefficiently”, in that part of their energy will be lost in the form of heat.

Thus, a solar cell can be “optimized” for light having a certain frequency spectrum. For example, for the conversion of light of one single wave-length, a solar cell could basically be optimized by choosing a material with a band-gap value just below the photon energy of the light.

However, sunlight has a broad frequency spectrum, which implies that if the energy conversion takes place by using one single type of solar cell with one single band gap value, the efficiency of the system will inevitably be low (due to loss of the “excess energy” of photons with “high” energy, and/or due to the fact that photons with “low” energy will not contribute to the production of electron-hole pairs).

This problem is well known in the art and many approaches for solving it (at least partially) are known. For example, one known approach is based on the use of multiple band gap solar cells, with “stacked” absorbing regions or subcells (basically corresponding to pn junctions). The absorbing regions or subcells can be stacked so that the photon first arrives at a subcell having a high band gap, and thereafter (if not absorbed in that first subcell) passes through one or more further absorbing subcells, each with a lower band gap value than the preceding one. Thus, basically, the photon can be “absorbed” in the subcell that provides for a minimum loss of excess energy in the form of heat. Examples of this type of solar cell and related problems are discussed in, for example, the following documents, all of which are incorporated herein by reference: U.S. Pat. No. 4,128,733, U.S. Pat. No. 4,179,702, WO-A-91/04580, U.S. Pat. No. 5,720,827, U.S. Pat. No. 6,469,241, US-A-2003/0136442, US-A-2004/0118451, US-A-2007/0227588, US-A-2008/0029151, US-A-2008/0163924, US-A-2008/0178931.

It is clear from these documents that the use of more than one band gap can help to enhance the energy conversion efficiency of the solar cell. However, providing a large number of different band gaps also involves problems, such as, for example, problems related to the incompatibility of materials and structures, process control (for example, when growing multiple layers of different semiconductor materials vertically upward from a substrate), free carrier absorption of photons (which can reduce the photon flux available at the lower band gap subcells in a stack when the stack becomes high), etc.

Thus, in practice, solar cells will have a limited number of band gap values (such as 2-4 band gap values) and thus be more appropriate for converting light with a limited frequency spectrum. It can be said that a solar cell is “optimized” for a certain frequency spectrum, or at least “better adapted” to a certain frequency spectrum than to another frequency spectrum. Compound semiconductor solar cells, based on III-V compounds, are often provided with 2-4 subcells, such as 3 subcells, with different band gap values, and by selecting these band gap values accordingly, the solar cells can be “optimized” for converting light having a certain frequency spectrum into electrical energy, with a minimum of losses due to non-absorbed photons and due to photons absorbed by a sub-cell having a band gap value excessively below the energy of the absorbed photons.

WO-A-91/04580 and U.S. Pat. No. 6,469,241 mentioned above propose alternatives to the “vertical stacking” of band gaps. These alternatives are based on splitting or dispersing the sunlight in accordance with its frequencies, basically so that photons corresponding to certain frequency ranges can be directed towards respective solar cells having band gaps adapted to said frequency ranges. That is, instead of “vertically” stacking “subcells” with different band gaps, solar cells with different band gaps can be distributed “horizontally” and the sunlight can be split into different portions in accordance with its frequencies, and the different portions can then be directed to impinge on the solar cells best adapted for converting the corresponding frequencies into electrical energy. However, this requires, for example, additional equipment related to the splitting/dispersion of the light and the control thereof.

Efficiency is a crucial aspect of solar cell based systems for the production of electrical power. One of the problems with solar power is the need to make it “cost competitive” with other power sources. Solar cells are not inexpensive, inter alia due to the material and fabrication costs.

The efficiency of a solar cell, its “energy conversion efficiency”, is basically the percentage of the power of the light that impinges on the solar cell that is collected as electrical power. The efficiency is normally stated with reference to “standard test conditions”, STC, which implies a temperature of 25° C., an irradiance of 1000 W/m² with an air mass 1.5 (AM1.5) spectrum, which basically corresponds to the irradiance and spectrum of sunlight incident on a clear day upon a sun-facing 37°-tilted surface with the sun at an angle of 41.81° above the horizon.

In order to make better use of the available solar cells, solar light concentrators are normally used to collect and concentrate the sunlight, so that the irradiance on the solar cells is higher than the irradiance on the system in its entirety. Typically, III-V compound solar cells have an energy conversion efficiency of 31% (at AM 1.5G) under normal operating conditions, and this conversion efficiency can be increased to over 37% by using concentrators. Also, by concentrating the sunlight, the number of solar cells needed can be reduced. For example, if a collector such as a lens is used that “collects” the light impinging on a lens area of approximately 500 cm² and focuses it onto a solar cell with an area of 1 cm², the amount of solar cells necessary for a solar module or array can be reduced by a factor of approximately 500. That is, the concentrators not only help to increase the efficiency of the individual cells, but also reduce the number of cells needed for a solar array. One is in essence replacing expensive semiconductor material with relatively inexpensive lens material.

Thus, by using concentrators and other equipment (such as solar tracking equipment, for example as disclosed in US-A-2008/0029151 mentioned above), the amount of solar energy that is directed to the solar cells can be optimized and the conversion efficiency of the cells can be increased, and the efficiency of the entire system can be further enhanced by optimizing the efficiency of the solar cells by adapting them to the solar frequency spectrum or by splitting to light so as to direct its different frequency components to different kinds of solar cells, each adapted to a respective frequency range. Although 100% efficiency is impossible to achieve, the skilled person will normally design a solar power system aiming at a cost-effective solution, keeping in mind not only the over-all efficiency of the system in regards to the percentage of the sunlight energy that is actually converted into electrical energy, but also the cost of the system.

### SUMMARY OF THE INVENTION

As mentioned above, the efficiency of a solar cell can be expressed with reference to STC, which inter alia implies an AM1.5 frequency spectrum. However, in practice, the light impinging on the solar cell will not have a perfect AM1.5 frequency spectrum; instead, the frequency spectrum of the sunlight (that is, the distribution of the total energy along the frequency range of the light) that arrives at the solar cells of a solar power system will vary during operation of the system. It will depend on factors such as the time of the day (as the position of the sun above the horizon will vary during the day) and also on other factors, such as the weather conditions (including, for example, the air pressure, the presence of clouds, the presence of dust, etc.). Thus, if a system has been “optimized” for operation under certain conditions (such as AM1.5 conditions), it may end up working “sub-optimally” for a large portion of the day (due to the position of the sun in the sky) and/or under certain weather conditions. Accordingly, the present disclosure additionally provides for sets of solar cells that have been optimized for an AM1.45 or less frequency spectrum (e.g. an AM1.45, AM1.40, AM1.35, or AM1.30, or even lower frequency spectrum); and sets of solar cells that have been optimized for an AM1.55 or greater frequency spectrum (e.g. an AM1.55, AM1.60, AM1.65, AM1.70, or even greater frequency spectrum).

In one aspect, the present disclosure provides a system including a solar cell assembly for the generation of electrical power from sunlight. In one embodiment, the system includes: a first set of solar cells including a plurality of entire sunlight spectrum solar cells adapted to an air mass 1.5 (AM1.5) light frequency spectrum so as to convert light having the AM1.5 light frequency spectrum into electrical energy with an optimized energy conversion efficiency, wherein each of the plurality of solar cells adapted to the AM1.5 light frequency spectrum includes a plurality of stacked subcells; a second set of solar cells including a plurality of entire sunlight spectrum solar cells adapted to an air mass 1.55 (AM1.55) or greater light frequency spectrum so as to convert light having the AM1.55 or greater light frequency spectrum into electrical energy with an optimized energy conversion efficiency, wherein each of the plurality of solar cells adapted to the AM1.55 or greater light frequency spectrum includes a plurality of stacked subcells; a third set of solar cells including a plurality of entire sunlight spectrum solar cells adapted to an air mass 1.45 (AM1.45) or less light frequency spectrum so as to convert light having the AM1.45 or less light frequency spectrum into electrical energy with an optimized energy conversion efficiency, wherein each of the plurality of solar cells adapted to the AM1.45 or less light frequency spectrum includes a plurality of stacked subcells; wherein the system is arranged to respond to changes in the frequency spectrum of the sunlight by causing the sunlight to selectively impinge on the first set of solar cells, the second set of solar cells, or the third set of solar cells, in accordance with the frequency spectrum of the sunlight, in order to enhance the energy conversion efficiency of the system.

In another aspect, the present disclosure provides a method for the generation of electrical power from sunlight. In one embodiments, the method includes: operating a solar cell assembly for the generation of electrical power from sunlight, the solar cell assembly including: a first set of solar cells including a plurality of entire sunlight spectrum solar cells adapted to an air mass 1.5 (AM1.5) light frequency spectrum so as to convert light having the AM1.5 light frequency spectrum into electrical energy with an optimized energy conversion efficiency, wherein each of the plurality of solar cells adapted to the AM1.5 light frequency spectrum includes a plurality of stacked subcells; a second set of solar cells including a plurality of entire sunlight spectrum solar cells adapted to an air mass 1.55 (AM1.55) or greater light frequency spectrum so as to convert light having the AM1.55 or greater light frequency spectrum into electrical energy with an optimized energy conversion efficiency, wherein each of the plurality of solar cells adapted to the AM1.55 or greater light frequency spectrum includes a plurality of stacked subcells; a third set of solar cells including a plurality of entire sunlight spectrum solar cells adapted to an air mass 1.45 (AM1.45) or less light frequency spectrum so as to convert light having the AM1.45 or less light frequency spectrum into electrical energy with an optimized energy conversion efficiency, wherein each of the plurality of solar cells adapted to the AM1.45 or less light frequency spectrum includes a plurality of stacked subcells; and responding to changes in the frequency spectrum of the sunlight by making the sunlight selectively impinge on the first set of solar cells, the second set of solar cells, or the third set of solar cells, in accordance with the frequency spectrum of the sunlight.

In another aspect, the present disclosure provides a method for the generation of electrical power from sunlight. In one embodiment, the method includes: operating a solar cell assembly for the generation of electrical power from sunlight, the solar cell assembly including: a first set of solar cells including a plurality of entire sunlight spectrum solar cells adapted to a light frequency spectrum for a first period of a year so as to convert light having the light frequency spectrum for the first period of the year into electrical energy with an optimized energy conversion efficiency, wherein each of the plurality of solar cells adapted the light frequency spectrum for the first period of the year includes a plurality of stacked subcells; a second set of solar cells including a plurality of entire sunlight spectrum solar cells adapted to a light frequency spectrum for a second period of a year so as to convert light having the light frequency spectrum for the second period of the year into electrical energy with an optimized energy conversion efficiency, wherein each of the plurality of solar cells adapted to the light frequency spectrum for the second period of the year includes a plurality of stacked subcells; a third set of solar cells including a plurality of entire sunlight spectrum solar cells adapted to a light frequency spectrum for a third period of a year so as to convert light having the light frequency spectrum for the third period of the year into electrical energy with an optimized energy conversion efficiency, wherein each of the plurality of solar cells adapted to the light frequency spectrum for the third period of the year includes a plurality of stacked subcells; and responding to changes in the frequency spectrum of the sunlight by making the sunlight selectively impinge on the first set of solar cells, the second set of solar cells, or the third set of solar cells, in accordance with the frequency spectrum of the sunlight.

In another aspect, the present disclosure relates to a system for the generation of electrical power from sunlight, comprising: a solar cell assembly comprising N sets of solar cells (for example, solar cells in line with those disclosed in some of the references discussed above), each set being adapted to a set-specific light frequency spectrum so as to convert light having said set-specific frequency spectrum into electrical energy with an optimized energy conversion efficiency (whereby “optimized” is to be interpreted in a relative sense, that is, basically in the sense that each set has a better energy conversion efficiency at its own set-specific frequency spectrum than the other sets), said set-specific frequency spectrum being different for each of said sets of solar cells (although this does not exclude the possibility of the system or assembly comprising more than one set having the same or similar characteristics), N is an integer greater than one, each set of solar cells comprising at least one solar cell comprising a plurality of stacked subcells.

The system is arranged to respond to changes in the frequency spectrum of the sunlight by causing the sunlight to selectively impinge on one or another of said N sets of solar cells, in accordance with the frequency spectrum of the sunlight, in order to enhance the energy conversion efficiency of the system.

Thus, it is achieved that when the frequency spectrum of the incoming sunlight changes, for example, due to changes in the position of the sun and/or due to changing weather conditions, the set of solar cells on which the sunlight impinges can be changed, thus providing for an enhanced energy conversion efficiency of the system. For example, one set of solar cells can be “active” during one part of the day, another set of solar cells can be “active” during another part of the day, etc. By appropriately selecting the set of solar cells on which the incoming sunlight impinges (for example, based on the time of the day, on measurements of the frequency spectrum of the sunlight, etc.), the set of solar cells best “adapted” for conversion of the solar energy into electrical energy can be used at each moment, thus increasing the conversion efficiency of the system.

The system can further comprise at least one concentrator, wherein the at least one concentrator is arranged to concentrate sunlight and to make it impinge on one set of solar cells.

The sets of solar cells can be displaceable, and the system can further comprise a structure for displacing the sets of solar cells with regard to said at least one concentrator so that, according to the position of the sets of solar cells with regard to said at least one concentrator, sunlight impinges one on or another of said sets of solar cells.

The system can further comprise a control system associated with said structure for displacing the sets of solar cells with regard to said at least one concentrator, for controlling movement of said sets of solar cells in accordance with at least one input parameter. This at least one input parameter can include the time, so that during at least one period of the day sunlight will impinge on one of said sets of solar cells, and during at least another period of the day sunlight will impinge on another of said sets of solar cells.

The system can comprise at least one concentrator arranged to concentrate sunlight and to make it impinge on one set of solar cells, said at least one concentrator being displaceable so as to selectively redirect light towards one or another of said sets of solar cells.

The system can further comprise a structure for displacing the sets of solar cells, and a control system associated with said structure for displacing the sets of solar cells, for controlling movement of said sets of solar cells in accordance with at least one input parameter (which can include the time, so that during at least one period of the day sunlight will impinge on one of said sets of solar cells, and during at least another period of the day sunlight will impinge on another of said sets of solar cells). The control system can include a processor that receives input (e.g., time of day or time of year) to determine the displacement required during each period (e.g., time of day or time of year) such that during at least a first period the sunlight will impinge on the first set of solar cells, during at least a second period the sunlight will impinge on the second set of solar cells, and during at least a third period the sunlight will impinge on the third set of solar cells

The solar cells can, for example, be III-V compound solar cells.

One of said sets of solar cells can comprise solar cells having a first set of band gaps, and another of said sets of solar cells can comprise solar cells having a second set of band gaps, said first set of band gaps differing from said second set of band gaps. Thus, one of said sets of solar cells can be better adapted for converting sunlight into electrical energy when the sunlight impinging on the system has a first frequency spectrum, and said another set of solar cells can be better adapted for conversion when the sunlight has a second frequency spectrum different from the first one.

Each set of solar cells can comprises a plurality of substantially identical solar cells.

Another aspect of the invention relates to a method for the generation of electrical power from sunlight, comprising: operating a solar cell assembly for producing electrical power, said solar cell assembly comprising N sets of solar cells, each set being adapted to a set-specific light frequency spectrum so as to convert light having said set-specific frequency spectrum into electrical energy with an optimized energy conversion efficiency, said set-specific frequency spectrum being different for each of said sets of solar cells, N is an integer greater than one, each set of solar cells comprising at least one solar cell comprising a plurality of stacked subcells; and responding to changes in the frequency spectrum of the sunlight by making the sunlight selectively impinge on one or another of said N sets of solar cells, in accordance with the frequency spectrum of the sunlight. What has been said regarding the system above also applies to the method, mutatis mutandis.

For example, the method can comprise using at least one concentrator to concentrate sunlight and to make it impinge on one set of solar cells. The step of responding to changes in the frequency spectrum of the sunlight can thus comprise displacing the sets of solar cells with regard to said at least one concentrator so that, according to the position of the sets of solar cells with regard to said at least one concentrator, sunlight impinges one on or another of said sets of solar cells. The step of responding to changes in the frequency spectrum of the sunlight can comprise displacing said sets of solar cells with regard to said at least one concentrator in accordance with the time of the day, so that during at least one period of the day sunlight will impinge on one of said sets of solar cells, and during at least another period of the day sunlight will impinge on another of said sets of solar cells.

The method can comprise displacing at least one concentrator so as to selectively redirect light towards one or another of said sets of solar cells.

The step of responding to changes in the frequency spectrum of the sunlight can comprise displacing the sets of solar cells in accordance with at least one input parameter, such as the time, so that during at least one period of the day sunlight will impinge on one of said sets of solar cells, and during at least another period of the day sunlight will impinge on another of said sets of solar cells.

Additional advantages and features will become apparent to those skilled in the art from this disclosure, including the following detailed description. While the invention is described below with reference to implementations thereof, the invention is not limited to those implementations. Those of ordinary skill in the art having access to the teachings herein will recognize additional applications, modifications and implementations, which are within the scope of the invention as disclosed and claimed herein and with respect to which the invention could be of utility.

### BRIEF DESCRIPTION OF THE DRAWINGS

The drawings comprise the following figures:

FIG. 1 schematically illustrates the AM1.5 spectrum.

FIG. 2 schematically illustrates two different kinds of solar cells with different band gap values.

FIG. 3 schematically illustrates part of a system in accordance with one possible embodiment of the invention.

FIG. 4 schematically illustrates a detail of an alternative embodiment of the invention.

FIG. 5 schematically illustrates a solar array arrangement in accordance with one possible embodiment of the invention.

### DESCRIPTION OF EMBODIMENTS OF THE INVENTION

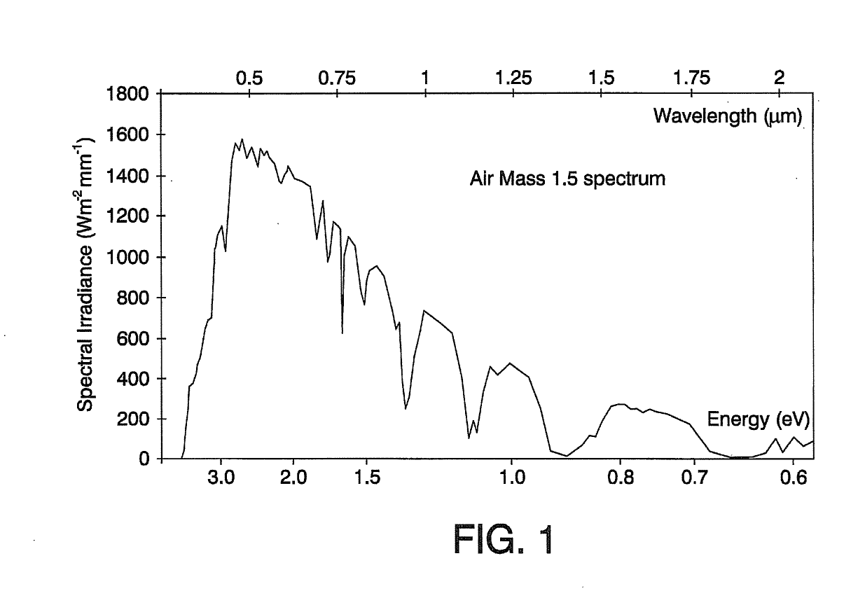

FIG. 1 schematically illustrates the frequency spectrum of the sunlight at air mass 1.5 (AM1.5), that is, how the energy of the sunlight is distributed over the frequency range at AM1.5. Now, as mentioned above, when a solar array of a sun power system receives the sunlight, in practice the frequency spectrum of the light that impinges on the solar cell does not have a perfect AM1.5 spectrum. Also, the spectrum will vary during the day and also according to the weather conditions. Thus, to simply put it: a solar cell having a set of subcells “optimized” for the frequency spectrum of the sun in the morning, will not be optimal for energy conversion at noon.

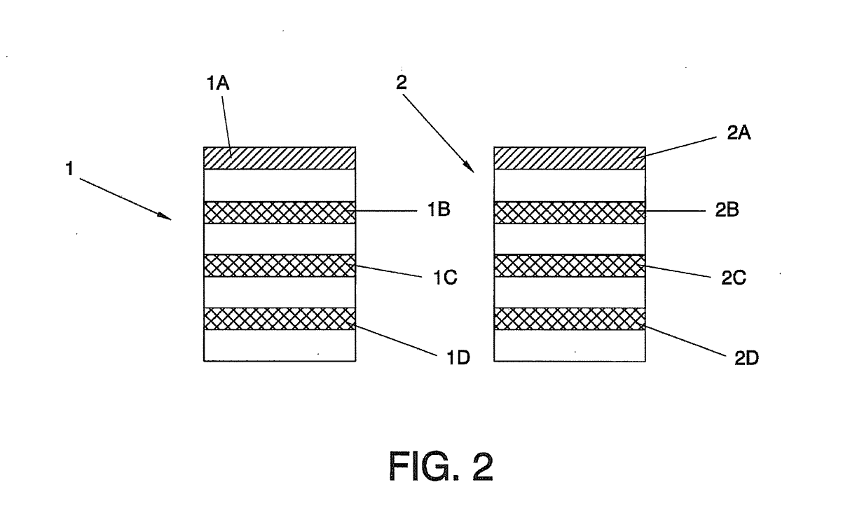

FIG. 2 schematically illustrates two solar cells 1 and 2, each comprising a top structure 1A and 2A, respectively, including for example a glass layer, and three subcells 1B-1C-1D and 2B-2C-2D, respectively. For example, the cells can be III-V compound cells of the type described in WO-A-2008/0029151 or in other of the documents referred to above, or other multi/junction solar cells, for example as known in the art.

One of said solar cells 1 can be “adapted” to the solar spectrum at noon. Such a cell can, for example, comprise three band gaps, whereby subcell 1B can feature a band gap in the range of approximately 2-2.2 eV, subcell 1C a band gap in the range of approximately 1.2-1.6 eV, and subcell 1D a band gap in the range of approximately 0.8-1.2 eV.

Another of said solar cells 2 can be “adapted” to the solar spectrum early in the morning and late in the afternoon. For example, subcell 2B can feature a band gap in the order of approximately 1.96 eV, subcell 2C a band gap in the order of approximately 1.0 eV, and subcell 2D a band gap in the range of approximately 0.67 eV.

In any case, in practice, the skilled person can choose solar cells with suitable band gap values considering, for example, issues such as the solar spectrum at different times and at the relevant geographical location(s), commercial availability of solar cells with suitable band gaps, price, and other practical issues.

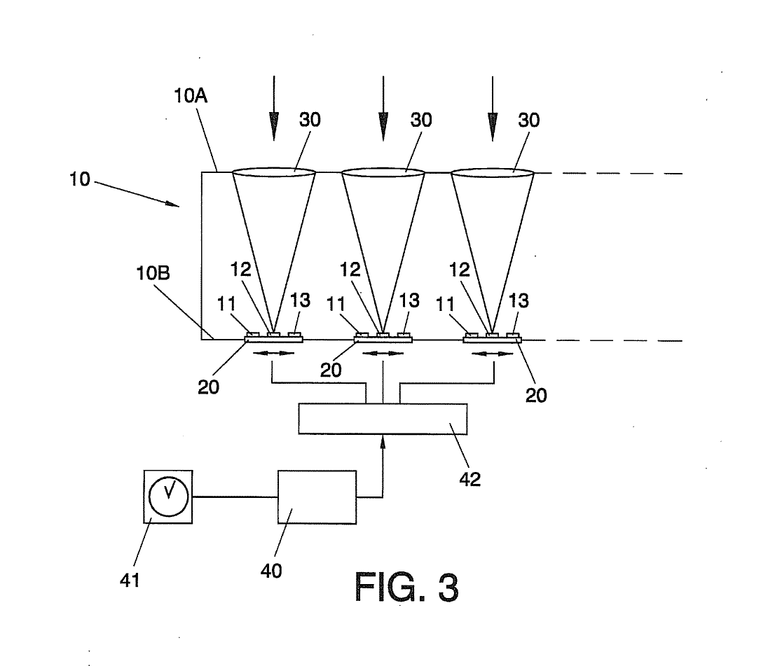

FIG. 3 schematically illustrates one possible embodiment of the invention. It illustrates a solar panel comprising a plurality of solar cells 11 which make up (or form part of) a first set of solar cells, and a plurality of solar cells 12 which make up (or form part of) a second set of solar cells. The solar cells 11 can be substantially as the cells 1 described above, and the solar cells 12 can be substantially as the solar cells 2 described above. However, many other possible implementations exist. Further, there can be even further sets of solar cells. For example, there can be an additional set of solar cells 13, as schematically illustrated in FIG. 3. Each set of solar cells is “adapted” for “optimal” conversion efficiency at a certain solar light frequency spectrum. If there are two sets, one can be optimized for “noon” conditions and one can be optimized for “early morning/late afternoon” conditions. The number of different “sets” to be used will in practice be determined by the skilled person in view of practical issues such as the trade-off between the benefits involved with an “optimized” conversion and the additional costs involved with the increased number of solar cells and the equipment needed for “setting” the sunlight onto the relevant set of solar cells at the right time and/or under the appropriate conditions.

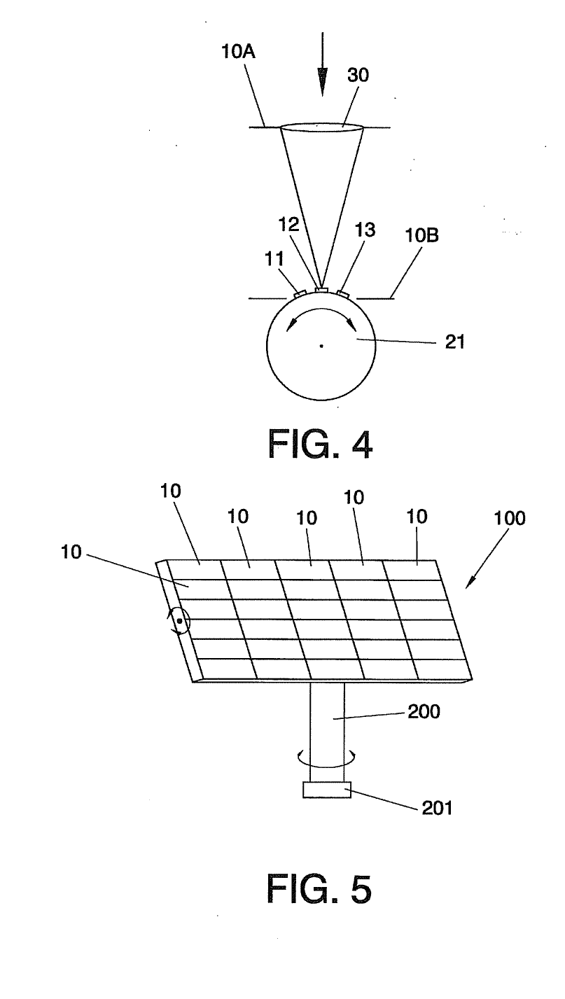

In the illustrated embodiment, the solar cells are placed in correspondence with a bottom portion 10B of the solar panel 10. The solar cells 11-13 are placed on supports 20 which are moveable with regards to said bottom portion, in a direction substantially parallel with the surface of said bottom portion (for example, linearly as schematically illustrated by the arrows in FIG. 3, or by rotation around an axis perpendicular to the bottom portion 10B). However, also other types of movement are possible, such as rotation in a plane perpendicular to the plane of the bottom portion 10B of the solar panel (as in the alternative embodiment schematically illustrated in FIG. 4, in which the solar cells 11-13 are mounted on a pivotable or rotatable element 21 which, for example, can be arranged above the bottom portion 10B of the solar panel, or in correspondence with openings in said bottom portion 10B, as illustrated in FIG. 4).

In the embodiment of the invention illustrated in FIG. 3, on each of said supports 20 there is at least one solar cell out of each set of solar cells, as schematically illustrated in FIG. 3. The solar cell is arranged on the support together with additional circuitry such as a by-pass diode (not shown).

At a top portion 10A of the solar panel, a plurality of concentrators 30 are arranged, such as for example Fresnel lenses, which can be of the type conventionally used in solar power systems. The Fresnel lenses are arranged to focus the sunlight towards a specific position at the bottom portion 10B of the solar panel 10.

The system illustrated in FIG. 3 further includes a control system 40, which receives a time signal from a clock 41 and which is operatively connected to an electromechanical subsystem 42 which is responsive to signals from the control system 40. The control system 40 is programmed to, on the basis of the timing signal, send the relevant control signals to the electromechanical subsystem 42, which is responsive to said signals so as to displace the supports 20 supporting the solar cells 11-13, in a manner so as to selectively move one of said sets of solar cells away from the light coming from the concentrators, and moving another one of said sets of solar cells into the light so that the light impinges on said set of solar cells. For example, if at noon the solar cells 11 are in the light, at a predetermined moment of the afternoon the supports can be displaced so that the solar cells 11 are brought out of the light and the solar cells 12 are brought into the light (in accordance with the arrangement illustrated in FIG. 3). Of course, at the same time, the conventional “sun tracking” movement of the solar array comprising the solar panels 10 can take place, assuring that the sun is always directed towards the concentrators 30 and the respective solar cells (Nov. 12, 2003) in an efficient manner.

Of course, instead of using the time as the basis for deciding which set of solar cells is to be placed to receive the sunlight, also other inputs can be used, as an alternative or as a complement to the time. For example, real-time measurements on the solar spectrum can be performed, for example with a spectral radiometer, and the result of said measurements can be used for deciding which set of solar cells is to be “activated”, that is, placed so that the sunlight impinges thereon.

FIG. 5 schematically illustrates a system for the generation of solar power comprising a solar array 100 comprising a plurality of solar panels 10 as described above, arranged in rows and columns. The array 100 is mounted on a vertical support structure 200 which is arranged rotatably with regard to its base, and the solar array is further pivotable around a substantially horizontal axis. The system includes a control sub-system for tracking the sun, which can (but need not) integrate the control system 40 referred to above. Thus, enhanced power production is obtained by not only tracking the sun correctly and concentrating it onto multi-junction solar cells, but also by appropriately choosing the correct set of solar cells to be “on-sun” at a specific moment, for example, according to the time of the day.

In this text, the term “comprises” and its derivations (such as “comprising”, etc.) should not be understood in an excluding sense, that is, these terms should not be interpreted as excluding the possibility that what is described and defined may include further elements, steps, etc.

What is claimed is:

1. A system comprising a solar cell assembly for the generation of electrical power from sunlight, comprising:
a first set of solar cells comprising a plurality of entire sunlight spectrum solar cells adapted to an air mass 1.5 (AM1.5) light frequency spectrum so as to convert light having the AM1.5 light frequency spectrum into electrical energy with an optimized energy conversion efficiency, wherein each of the plurality of solar cells adapted to the AM1.5 light frequency spectrum comprises a plurality of stacked subcells;
a second set of solar cells comprising a plurality of entire sunlight spectrum solar cells adapted to an air mass 1.55 (AM1.55) or greater light frequency spectrum so as to convert light having the AM1.55 or greater light frequency spectrum into electrical energy with an optimized energy conversion efficiency, wherein each of the plurality of solar cells adapted to the AM1.55 or greater light frequency spectrum comprises a plurality of stacked subcells;
a third set of solar cells comprising a plurality of entire sunlight spectrum solar cells adapted to an air mass 1.45 (AM1.45) or less light frequency spectrum so as to convert light having the AM1.45 or less light frequency spectrum into electrical energy with an optimized energy conversion efficiency, wherein each of the plurality of solar cells adapted to the AM1.45 or less light frequency spectrum comprises a plurality of stacked subcells;
wherein the system is arranged to respond to changes in the frequency spectrum of the sunlight by causing the sunlight to selectively impinge on the first set of solar cells, the second set of solar cells, or the third set of solar cells, in accordance with the frequency spectrum of the sunlight, in order to enhance the energy conversion efficiency of the system.

2. The system of claim 1, further comprising at least one concentrator, said at least one concentrator being arranged to concentrate sunlight and to make it impinge on the first set of solar cells, the second set of solar cells, or the third set of solar cells.

3. The system of claim 2, wherein said sets of solar cells are displaceable, the system further comprising a structure for displacing the sets of solar cells with regard to said at least one concentrator so that, according to the position of the sets of solar cells with regard to said at least one concentrator, sunlight impinges on the first set of solar cells, the second set of solar cells, or the third set of solar cells.

4. The system according to claim 3, further comprising a control system associated with said structure for displacing the sets of solar cells with regard to said at least one concentrator, for controlling movement of said sets of solar cells in accordance with at least one input parameter.

5. The system according to claim 4, wherein the control system comprises a processor that receives input regarding the time of day to determine the displacement required during each period of the day such that during at least a first period of the day sunlight will impinge on the first set of solar cells, during at least a second period of the day sunlight will impinge on the second set of solar cells, and during at least a third period of the day sunlight will impinge on the third set of solar cells.

6. The system of claim 1, further comprising at least one concentrator, said at least one concentrator being arranged to concentrate sunlight and to make it impinge on the first set of solar cells, the second set of solar cells, or the third set of solar cells; said at least one concentrator being displaceable so as to selectively redirect light towards the first set of solar cells, the second set of solar cells, or the third set of solar cells.

7. The system of claim 1, wherein the system further comprises a structure for displacing the sets of solar cells, and a control system associated with said structure for displacing the sets of solar cells, for controlling movement of said sets of solar cells in accordance with at least one input parameter.

8. The system of claim 7, wherein the control system comprises a processor that receives input regarding the time of day to determine the displacement required during each period of the day such that during at least a first period of the day sunlight will impinge on the first set of solar cells, during at least a second period of the day sunlight will impinge on the second set of solar cells, and during at least a third period of the day sunlight will impinge on the third set of solar cells.

9. The system of claim 1, wherein the solar cells are III-V compound solar cells.

10. The system of claim 1, wherein each cell of the plurality of entire sunlight spectrum solar cells adapted to the AM1.5 light frequency spectrum have a first set of band gaps; each cell of the plurality of entire sunlight spectrum solar cells adapted to the AM1.45 or less light frequency spectrum have a second set of band gaps that is different from the first set of band gaps; and each cell of the plurality of entire sunlight spectrum solar cells adapted to the AM1.55 or greater light frequency spectrum have a third set of band gaps that is different from the first and second sets of band gaps.

11. The system of claim 1, wherein each set of solar cells comprises a plurality of substantially identical solar cells.

12. A method for the generation of electrical power from sunlight, comprising:
operating a solar cell assembly for the generation of electrical power from sunlight, comprising:
a first set of solar cells comprising a plurality of entire sunlight spectrum solar cells adapted to an air mass 1.5 (AM1.5) light frequency spectrum so as to convert light having the AM1.5 light frequency spectrum into electrical energy with an optimized energy conversion efficiency, wherein each of the plurality of solar cells adapted to the AM1.5 light frequency spectrum comprises a plurality of stacked subcells;
a second set of solar cells comprising a plurality of entire sunlight spectrum solar cells adapted to an air mass 1.55 (AM1.55) or greater light frequency spectrum so as to convert light having the AM1.55 or greater light frequency spectrum into electrical energy with an optimized energy conversion efficiency, wherein each of the plurality of solar cells adapted to the AM1.55 or greater light frequency spectrum comprises a plurality of stacked subcells;
a third set of solar cells comprising a plurality of entire sunlight spectrum solar cells adapted to an air mass 1.45 (AM1.45) or less light frequency spectrum so as to convert light having the AM1.45 or less light frequency spectrum into electrical energy with an optimized energy conversion efficiency, wherein each of the plurality of solar cells adapted to the AM1.45 or less light frequency spectrum comprises a plurality of stacked subcells; and
responding to changes in the frequency spectrum of the sunlight by making the sunlight selectively impinge on the first set of solar cells, the second set of solar cells, or the third set of solar cells, in accordance with the frequency spectrum of the sunlight.

13. The method of claim 12, further comprising using at least one concentrator to concentrate sunlight and to make it impinge on the first set of solar cells, the second set of solar cells, or the third set of solar cells.

14. The method of claim 13, wherein the step of responding to changes in the frequency spectrum of the sunlight comprises displacing the sets of solar cells with regard to said at least one concentrator so that, according to the position of the sets of solar cells with regard to said at least one concentrator, sunlight impinges on the first set of solar cells, the second set of solar cells, or the third set of solar cells.

15. The method according to claim 14, wherein the step of responding to changes in the frequency spectrum of the sunlight comprises providing input regarding the time of day to a processor that determines the displacement required during each period of the day to displace said sets of solar cells with regard to said at least one concentrator, such that during at least a first period of the day sunlight will impinge on the first set of solar cells, during at least a second period of the day sunlight will impinge on the second set of solar cells, and during at least a third period of the day sunlight will impinge on the third set of solar cells.

16. The method of claim 12, further comprising displacing at least one concentrator so as to selectively redirect light towards the first set of solar cells, the second set of solar cells, or the third set of solar cells.

17. The method of claim 12, wherein the step of responding to changes in the frequency spectrum of the sunlight comprises displacing the sets of solar cells in accordance with at least one input parameter.

18. The method of claim 17, further comprising providing input regarding the time of day to a processor that determines the displacement required during each period of the day to displace said sets of solar cells with regard to said at least one concentrator, such that during at least a first period of the day sunlight will impinge on the first set of solar cells, during at least a second period of the day sunlight will impinge on the second set of solar cells, and during at least a third period of the day sunlight will impinge on the third set of solar cells.

19. The method of claim 12, wherein each cell of the plurality of entire sunlight spectrum solar cells adapted to the AM1.5 light frequency spectrum have a first set of band gaps; each cell of the plurality of entire sunlight spectrum solar cells adapted to the AM1.55 or greater light frequency spectrum have a second set of band gaps that is different from the first set of band gaps; and each cell of the plurality of entire sunlight spectrum solar cells adapted to the AM1.45 or less light frequency spectrum have a third set of band gaps that is different from the first and second sets of band gaps.

20. A method for the generation of electrical power from sunlight, comprising:
operating a solar cell assembly for the generation of electrical power from sunlight, comprising:
a first set of solar cells comprising a plurality of entire sunlight spectrum solar cells adapted to a light frequency spectrum for a first period of a year so as to convert light having the light frequency spectrum for the first period of the year into electrical energy with an optimized energy conversion efficiency, wherein each of the plurality of solar cells adapted the light frequency spectrum for the first period of the year comprises a plurality of stacked subcells;
a second set of solar cells comprising a plurality of entire sunlight spectrum solar cells adapted to a light frequency spectrum for a second period of a year so as to convert light having the light frequency spectrum for the second period of the year into electrical energy with an optimized energy conversion efficiency, wherein each of the plurality of solar cells adapted to the light frequency spectrum for the second period of the year comprises a plurality of stacked subcells;
a third set of solar cells comprising a plurality of entire sunlight spectrum solar cells adapted to a light frequency spectrum for a third period of a year so as to convert light having the light frequency spectrum for the third period of the year into electrical energy with an optimized energy conversion efficiency, wherein each of the plurality of solar cells adapted to the light frequency spectrum for the third period of the year comprises a plurality of stacked subcells; and
responding to changes in the frequency spectrum of the sunlight by making the sunlight selectively impinge on the first set of solar cells, the second set of solar cells, or the third set of solar cells, in accordance with the frequency spectrum of the sunlight.
